(19) United States
(12) Patent Application Publication
(10) Pub. No.: US 2017/0062522 A1
(43) Pub. Date: Mar. 2, 2017

(54) Combining Materials in Different Components of Selector Elements of Integrated Circuits

(71) Applicant: Intermolecular, Inc., San Jose, CA (US)

(72) Inventors: Salil Mujumdar, San Jose, CA (US); Abhijit Pethe, San Jose, CA (US); Ashish Bodke, San Jose, CA (US); Kevin Kashefi, San Ramon, CA (US)

(73) Assignee: Intermolecular, Inc., San Jose, CA (US)

(21) Appl. No.: 15/235,992

(22) Filed: Aug. 12, 2016

Related U.S. Application Data
(60) Provisional application No. 62/210,773, filed on Aug. 27, 2015.

(51) Int. Cl. H01L 27/24; G11C 13/00; H01L 45/00

(52) U.S. Cl. CPC H01L 27/24; H01L 45/12; H01L 45/145; G11C 13/0002; G11C 2213/79; G11C 2213/72

(57) ABSTRACT

Provided are selector elements having snapback characteristics and non-volatile memory cells comprising such selector elements. To achieve its snapback characteristic, a selector element may include a dielectric layer comprising an alloy of two or more materials. In the same or other embodiments, the selector element may include a doped electrode, such carbon electrodes doped with silicon, germanium, and/or selenium. Concentrations of different materials forming an alloy may vary throughout the thickness of the dielectric layer. For example, the concentration of the first one alloy material may be higher in the center of the dielectric layer than near the interfaces of the dielectric layer with the electrodes. Some examples of this alloy material include germanium, indium, and aluminum. Examples of other materials in the same alloy include silicon, gallium, arsenic, and antimony. In some embodiments, the alloy is formed by three or more elements, such as indium gallium arsenic.

### CROSS-REFERENCE TO RELATED APPLICATIONS

This application claims the benefit under 35 U.S.C. §119(e) of US Provisional Patent Application 62/210,773, entitled: “Combining Materials in Different Components of Selector Elements of Integrated Circuits” filed on 2015-08-27, which is incorporated herein by reference in its entirety for all purposes.

### BACKGROUND

Nonvolatile memory elements are used in systems in which persistent storage is required. For example, digital cameras use nonvolatile memory cards to store images and digital music players use nonvolatile memory to store audio data. Nonvolatile memory is also used to persistently store data in computer environments. Nonvolatile memory is often formed using electrically-erasable programmable read only memory (EPROM) technology. This type of nonvolatile memory contains floating gate transistors that can be selectively programmed or erased by application of suitable voltages to their terminals.

As fabrication techniques improve, it is becoming possible to fabricate nonvolatile memory elements with increasingly smaller dimensions. However, as device dimensions shrink, scaling issues are posing challenges for traditional nonvolatile memory technology. This has led to the investigation of alternative nonvolatile memory technologies, including magnetoresistive random access memory (MRAM), ferroelectric random access memory (FRAM), phase change memory (PCM), spin transfer torque random access memory (STT-RAM), and resistive random access memory (ReRAM), among others.

Resistive memory devices are formed using memory elements that have two or more stable states with different resistances. Bistable memory has two stable states. A bistable memory element can be placed in a high resistance state or a low resistance state by application of suitable voltages or currents. Voltage pulses are typically used to switch the memory element from one resistance state to the other. Nondestructive read operations can be performed to ascertain the value of a data bit that is stored in a memory cell.

Resistive switching based on transition metal oxide switching elements formed of metal oxide films has been demonstrated. Although metal oxide films such as these exhibit bistability, the resistance of these films and the ratio of the high-to-low resistance states are often insufficient to be of use within a practical nonvolatile memory device. For instance, the resistance states of the metal oxide film should preferably be significant as compared to that of the system (e.g., the memory device and associated circuitry) so that any change in the resistance state change is perceptible. The variation of the difference in resistive states is related to the resistance of the resistive switching layer. Therefore, a low resistance metal oxide film may not form a reliable nonvolatile memory device. For example, in a nonvolatile memory that has conductive lines formed of a relatively high resistance metal such as tungsten, the resistance of the conductive lines may overwhelm the resistance of the metal oxide resistive switching element. Therefore, the state of the bistable metal oxide resistive switching element may be difficult or impossible to sense. Furthermore, the parasitic resistance (or the parasitic impedance, in the actual case of time-dependent operation), (e.g. due to sneak current paths that exist in the system), may depend on the state of the system, such as the data stored in other memory cells. It is often preferable that the possible variations of the parasitic impedance be unsubstantial compared to the difference in the values of the high and low resistance of a memory cell.

Similar issues can arise from integration of the resistive switching memory element with current selector elements (also known as current limiter or current steering elements), such as diodes and/or transistors. Control elements (e.g. selector devices) in nonvolatile memory structures can screen the memory elements from sneak current paths to ensure that only the selected bits are read or programmed. Schottky diode can be used as a selector device, which can include p-n junction diode or metal-semiconductor diode, however, this requires high thermal budget that may not be acceptable for 3-dimensional (3D) memory application. Metal-Insulator-Metal Capacitor (MIMCAP) tunneling diodes may have a challenge of providing controllable low barrier height and low series resistance. In some embodiments, the control element can also function as a current limiter or control element. In some embodiments, a control element can suppress large currents without affecting acceptable operation currents in a memory device. For example, a control element can be used with the purpose of increasing the ratio of the measured resistances in the high and low resistance state, further making the non-volatile memory device less susceptible to the noise due to parasitic impedances in the system. Note that the terms “control element”, “current selector”, “current limiter”, and “steering element” may often times be substituted for each other, due to a substantial overlap in the functional utility of the elements they may describe. Such a substitution does not affect the scope of this description, which is limited only by the claims.

Therefore, there is a need for a control element that can meet the design criteria for advanced memory devices.

### SUMMARY

Provided are selector elements having snapback characteristics and non-volatile memory cells comprising such selector elements. To achieve its snapback characteristic, a selector element may include a dielectric layer comprising an alloy of two or more materials. In the same or other embodiments, the selector element may include a doped electrode, such carbon electrodes doped with silicon, germanium, and/or selenium. Concentrations of different materials forming an alloy may vary throughout the thickness of the dielectric layer. For example, the concentration of the first one alloy material may be higher in the center of the dielectric layer than near the interfaces of the dielectric layer with the electrodes. Some examples of this alloy material include germanium, indium, and aluminum. Examples of other materials in the same alloy include silicon, gallium, arsenic, and antimony. In some embodiments, the alloy is formed by three or more elements, such as indium gallium arsenic.

In some embodiments, a selector element having a snapback characteristic comprises a first electrode, a dielectric layer, and a second electrode. The dielectric layer is disposed between the first electrode and the second electrode. In some instances, the dielectric layer may directly interface one or both electrodes. The dielectric layer may be characterized by a thickness extending in a direction between the first electrode and the second electrode. The dielectric layer comprises an alloy of a first material and a second material. Furthermore, the concentration of the first material and the concentration of the second material in the alloy vary throughout the thickness of the dielectric layer.

In some embodiments, the first material is selected from the group consisting of germanium, indium, and aluminum. The second material may be selected from the group consisting of silicon, a combination of gallium and arsenic, and a combination of arsenic and antimony. For example, the first material may be germanium, while the second material may be silicon. In some embodiments, the first material is selected from the group consisting of indium and aluminum, while the second material is selected from the group consisting of a combination of gallium and arsenic and a combination of arsenic and antimony. For example, the first material may be indium, while the second material may be a combination of gallium and arsenic or a combination of arsenic and antimony. Alternatively, the first material may be aluminum, while the second material may be combination of gallium and arsenic.

In some embodiments, the concentration of the first material and the concentration of the second material in the alloy vary gradually throughout the thickness of the dielectric layer. More specifically, the concentrations may vary linearly. In some embodiments, the concentration of the first material increase from the side of the dielectric layer facing the first electrode to the center of the dielectric layer.

In some embodiments, the first electrode comprises carbon and a dopant. The may be one of silicon, germanium, or selenium. Alternatively, the dopant may be one of nitrogen or oxygen. In some embodiments, the dopant has a concentration on the first electrode of between about 5 atomic % and 50 atomic % or, more specifically, between about 10 atomic % and 30 atomic %.

Also provided is a non-volatile memory cell. In some embodiments, the non-volatile memory cell comprises a non-volatile memory element and a selector element connected in series with the non-volatile memory element. Various examples of the selector element are described above. Specifically, the selector element may comprise a first electrode, a dielectric layer, and a second electrode. The dielectric layer is disposed between the first electrode and the second electrode. In some instances, the dielectric layer may directly interface one or both electrodes. The dielectric layer may be characterized by a thickness extending in a direction between the first electrode and the second electrode. The dielectric layer comprises an alloy of a first material and a second material. Furthermore, the concentration of the first material and the concentration of the second material in the alloy vary throughout the thickness of the dielectric layer. The non-volatile memory element may be a resistive switching memory element. As such, the non-volatile memory cell may be a resistive random access memory (ReRAM) cell.

### BRIEF DESCRIPTION OF THE DRAWINGS

To facilitate understanding, identical reference numerals have been used, where possible, to designate identical elements that are common to the figures. The drawings are not to scale and the relative dimensions of various elements in the drawings are depicted schematically and not necessarily to scale.

The techniques of the present invention can readily be understood by considering the following detailed description in conjunction with the accompanying drawings, in which:

FIG. 1 is a schematic illustration of performance characteristics of a selector element, in accordance with some embodiments.

FIG. 2A is a schematic illustration of a selector element, in accordance with some embodiments.

FIG. 2B is a schematic illustration of a non-volatile memory cell comprising a selector element, in accordance with some embodiments.

FIGS. 3A-3C are schematic illustration of three bandgap diagrams, in accordance with some embodiments.

FIGS. 4A-4E are schematic illustration of different concentration profiles in the dielectric layer, in accordance with some embodiments.

FIG. 5 illustrates snapback characteristics of carbon electrode/silicon dielectric/carbon electrode (C/Si/C) stack for different thicknesses of silicon dielectric layers, in accordance with some embodiments.

FIG. 6 is a schematic illustration of leakage characteristics in a selector element having a doped electrode, in accordance with some embodiments.

FIG. 7 illustrates a cross point memory array, in accordance with some embodiments.

### DETAILED DESCRIPTION

In the following description, numerous specific details are set forth in order to provide a thorough understanding of the presented concepts. The presented concepts may be practiced without some or all of these specific details. In other instances, well known process operations have not been described in detail so as to not unnecessarily obscure the described concepts. While some concepts will be described in conjunction with the specific embodiments, it will be understood that these embodiments are not intended to be limiting.

Non-volatile memory (NVM) devices, such as resistive random-access memory (ReRAM) and dynamic random-access memory (DRAM), may use selector elements to ensure that only selected memory elements of a memory array are accessed during read and write operations. A selector element may be positioned in series with a memory element. A combination of a memory element and a selector element may be referred to as a memory cell. In some embodiments, the selector element and the memory cell may be positioned in the same stack and may even share some components, such as electrodes.

Selector elements are devices with non-linear current-voltage (IV) characteristics. Specifically, a current passing through the selector element may be very low, when the voltage applied across the selector element is less than threshold voltage (Vth). However, when the voltage applied across it exceeds the threshold voltage, there is a very rapid increase in the electrical current through the selector element. In other words, a selector element of associated with a memory element is turned on when the threshold voltage is exceeded, which allows the current to flow through the memory cell including the selector element and memory element. As such, a selector element may have a threshold voltage (Vth) in a certain range associated with operating characteristics of a memory cell.

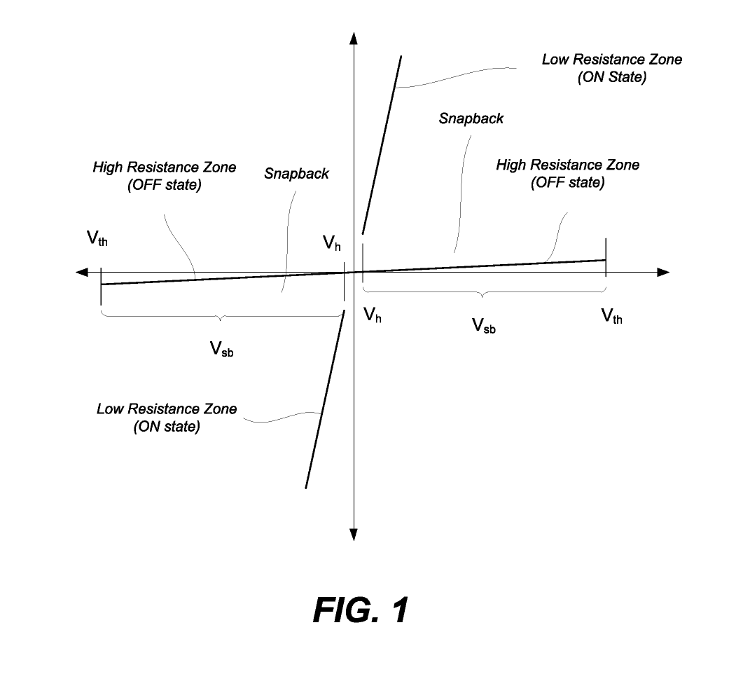

Another characteristic of a selector element is a snapback. This phenomenon will now be explained in more detail with reference to FIG. 1, which illustrates I-V characteristics of a selector element. Specifically, the selector element operates in its high resistance zone and allows very electrical current to pass up until voltage reaches the threshold voltage (Vₜₕ). Once the voltage increases beyond Vth, the voltage snaps back to a hold voltage (Vₕ) and a current through the selector element increases significantly. The selector element now operates in its low resistance zone. This S-shaped I-V characteristic is called snapback. The snapback voltage (V_{sb}) equals the threshold voltage (Vₜₕ) minus the hold voltage (Vₕ) as shown by Formula 1:

V_{sb}=Vₜₕ−Vₕ (Formula 1)

In other words, the snapback voltage is the voltage drop across the selector element as its switches to the ON state.

The snapback operation of the selector element may be used to keep the ON state voltage of the selector element under the maximum supply voltage, V_{cell}. Without the snapback, the ON state voltage would exceed that maximum supply voltage. However, the selector element with snapback characteristics not only switched to the ON state when Vₜₕ is exceeded, but also switched back to the OFF state when the voltage drops below the hold voltage (Vh). Furthermore, the selector element can also provide linear metal-like IV characteristics for the resistive memory element once it is turned to the ON state.

Some examples of selector elements that yield S-shaped IV characteristics (exhibit snapback) include, but not limited, to multi-component oxides and alloys of metals from groups 4, 5, or 6 of the periodic table. These metals have partially filled valence d-shells. These materials may behave as insulators (e.g., with negligible leakage currents) at relatively low biases in the OFF state when biased below the threshold voltage (Vₜₕ). Furthermore, these materials may act as metals (e.g., conducting high currents) at relatively low biases when switched to the ON state. This transition is reversible. When the bias is removed, the material returns to original insulating OFF state. Specific examples of suitable oxides include vanadium oxide, manganese oxide, titanium oxide, or combinations thereof. Other so-called MOTT insulators may also be used as a selector insulator. Examples include iron oxide, niobium oxide, tantalum oxide, or combination thereof.

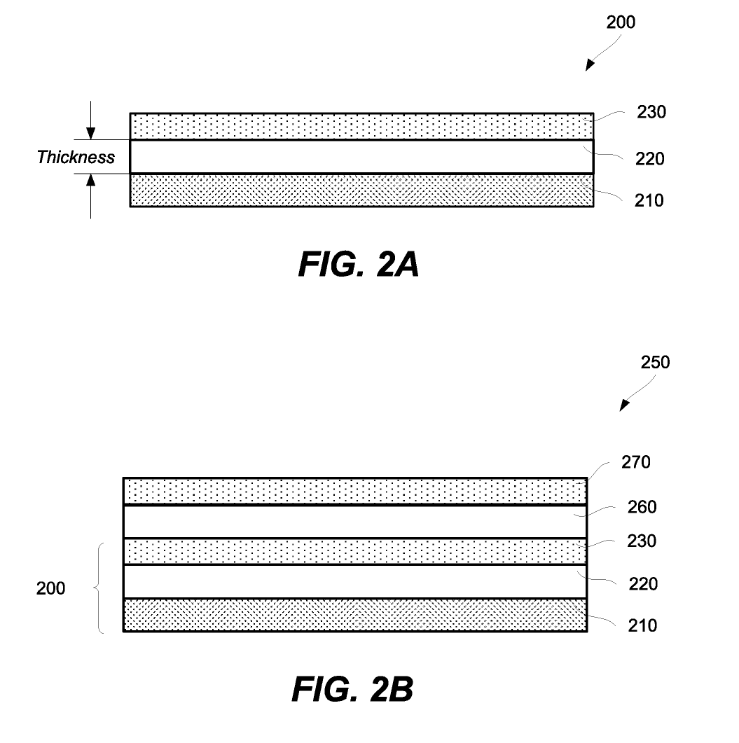

FIG. 2A is a schematic illustration of selector element 200, in accordance with some embodiments. Selector element 200 includes first electrode 210, dielectric layer 220, and second electrode 230. Dielectric layer 220 is disposed between first electrode 210 and second electrode 230. In some embodiments, dielectric layer 220 may directly interface both first electrode 210 and second electrode 230. Alternatively, dielectric layer 220 may be separated from first electrode 210 and second electrode 230 by other components, e.g., an interface layer. Dielectric layer 220 layer is characterized by a thickness extending in a direction between first electrode 210 and second electrode 230. The composition of dielectric layer 220 described below.

FIG. 2B is a schematic illustration of non-volatile memory cell 250 comprising selector element 200 and memory element 260, in accordance with some embodiments. Memory element 260 may share an electrode with selector element 200. In some embodiments, memory element 260 is a resistive switching memory element.

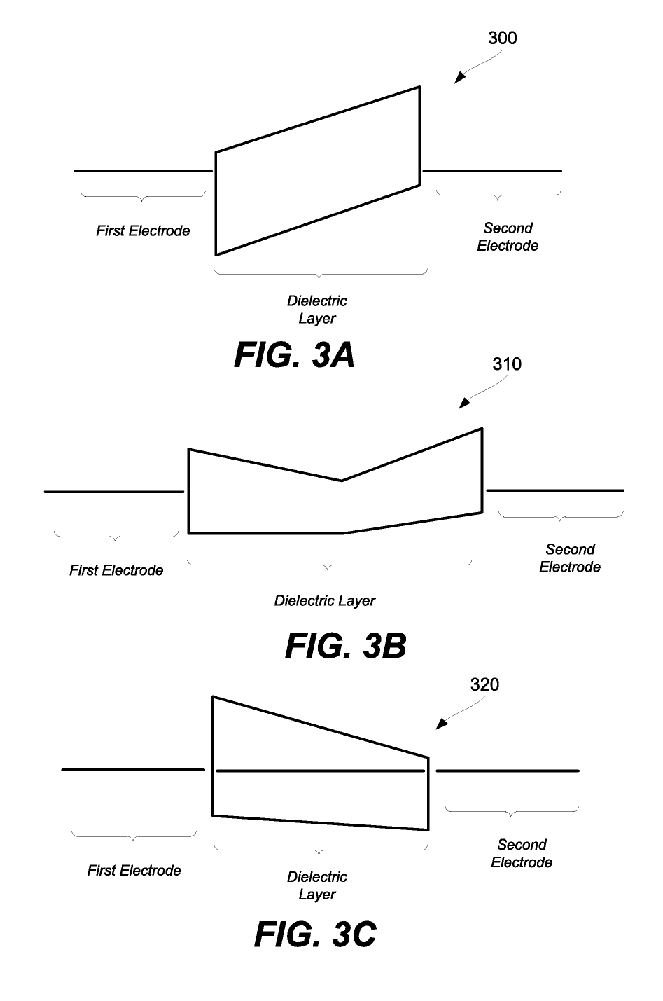

Selector elements may employ semiconductor materials to get a sharp turn-on/turn-off characteristics and specific snapback characteristics as described above. These application characteristics depend on various material characteristics of semiconductor materials, such as band-gap, tunneling masses, and barrier offsets with metals. It has been found that combining different semiconductor materials in alloys allows for better control of the material characteristics and, as a result, of selector element application characteristics. Some examples of these application characteristics are presented by bandgap diagrams illustrated in FIGS. 3A-3C. For example, combining materials with different barrier heights may be used to control leakage current (Jₗₑₐₖ). Materials with different band-gaps may be used to control snapback voltage (Vₛₙₐₚ) as well as leakage current (Jₗₑₐₖ). Furthermore, materials with different band-structures may be used.

In some embodiments, the dielectric layer comprises an alloy of a first material and a second material. As further below, the concentration of the first material and the concentration of the second material in the alloy vary throughout the thickness of the dielectric layer. In some embodiments, the first material is selected from the group consisting of germanium, indium, and aluminum. The second material may be selected from the group consisting of silicon, a combination of gallium and arsenic, and a combination of arsenic and antimony. The concentration ratio of the first material to the second material may be between about 0.1 and 10 or, more specifically, between about 0.1 and 1 or even between about 0.2 and 0.5. Alternatively, the concentration ratio of the first material to the second material may be between about 1 and 10 or, more specifically, between about 2 and 5.

For example, the first material may be germanium, while the second material may be silicon. In some embodiments, the first material is selected from the group consisting of indium and aluminum, while the second material is selected from the group consisting of a combination of gallium and arsenic and a combination of arsenic and antimony. For example, the first material may be indium, while the second material may be a combination of gallium and arsenic or a combination of arsenic and antimony. Alternatively, the first material may be aluminum, while the second material may be combination of gallium and arsenic.

In some embodiments, the dielectric layer allows may include one or more of Si₁₋ₓGeₓ, In₁₋ₓGaₓAs, Al₁₋ₓGaₓAs, or InAs₁₋ₓSbₓ. The value of X may vary between about 0.01 and 0.99, between about 0.10 and 0.90, between about 0.25 and 0.75, between about 0.40 and 0.60, between about 0.01 and 0.25, between about 0.01 and 0.10, between about 0.01 and 0.05. In general, the semiconductor material may include two or more materials from groups 4, 5, and 6 of the periodic table. Specifically, these elements include titanium (Ti), zirconium (Zr), hafnium (Hf), rutherfordium (Rf), vanadium (V), niobium (Nb), tantalum (Ta), dubnium (Db), chromium (Cr), molybdenum (Mo), tungsten (W), and seaborgium (Sg).

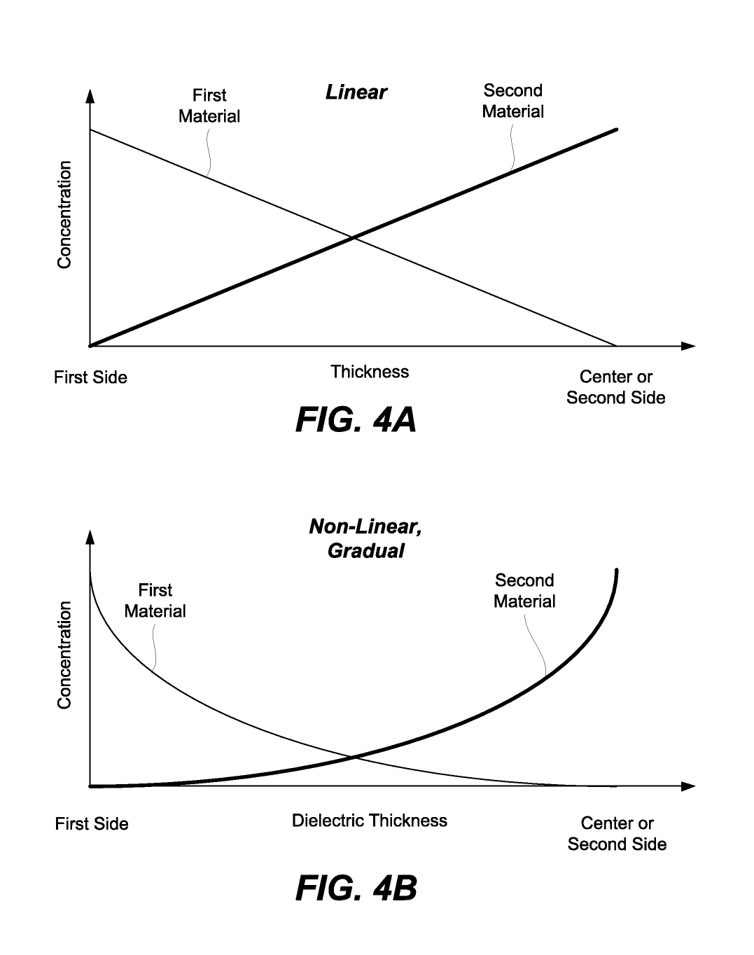

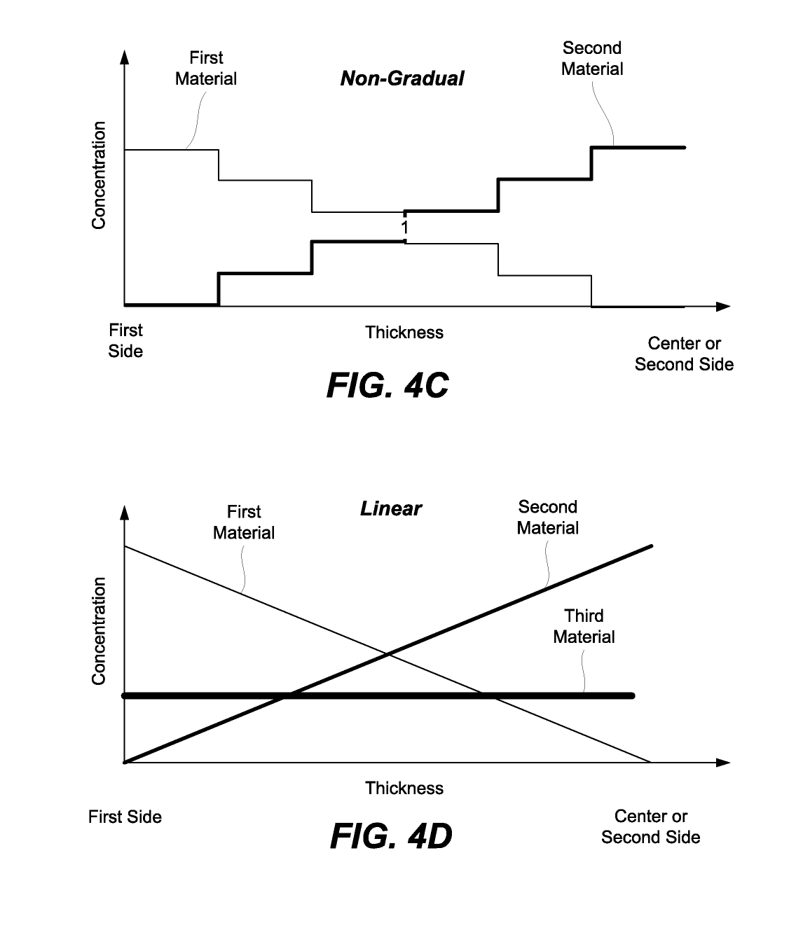

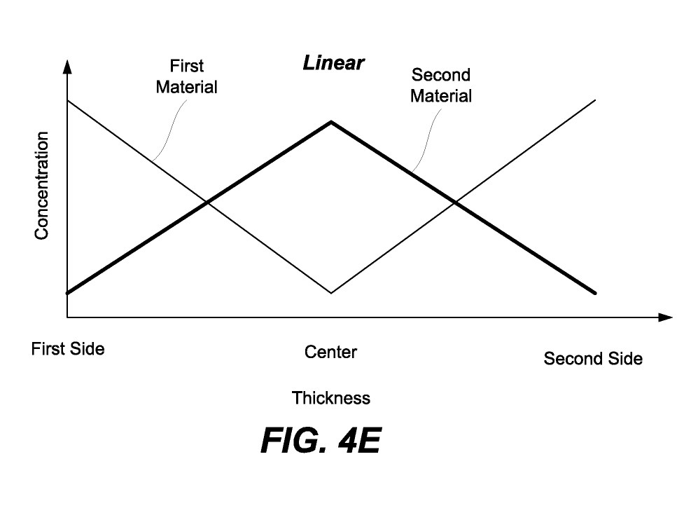

In some embodiments, semiconductor alloy gradation throughout the semiconductor thickness may be used, e.g., the concentration of the first material and the concentration of the second material in the alloy vary throughout the thickness of the dielectric layer. Such gradation may be used to provide greater flexibility in achieving particular selector performance characteristics. Some examples of alloy composition gradation are presented in FIGS. 4A-4E. Specifically, FIG. 4A illustrates a linear change in concentrations of the two materials with one concentration increasing from one side to another side or to the center of the dielectric layer while the other concentration is decreasing in the same direction. FIG. 4B illustrates a non-linear change but uniform in concentrations of two materials. The profiles may be achieved by simultaneous deposition of two materials and either varying power applied to different targets (e.g., during co-sputtering of two targets) or varying concentrations of precursors (e.g., during chemical vapor deposition or atomic layer deposition). Both examples may be referred to as gradual changes in concentrations.

FIG. 4C illustrates a stepped change in the concentrations of the two materials. This type of the dielectric layer may be formed using a nano-laminate or some other suitable techniques. For example, dielectric sub-layers having different ratios of the first and second materials may be stacked to form the dielectric layer.

FIG. 4D illustrates concentration profiles of three different materials forming an alloy of the dielectric layer. In this example, the concentrations of two materials are varies, while the concentration of the third material is constant.

FIG. 4E illustrates concentration profiles throughout the entire thickness of the dielectric layers. The concentration of one material (e.g., the second material in this example) may be at its maximum near the center of the dielectric layer, while the concentration of another material (e.g., the first material in this example) may be at its minimum at the center. The center may be defined as an area representing between about 5% and 25% of the thickness of the dielectric layer and equally spaced from both sides of the dielectric layer.

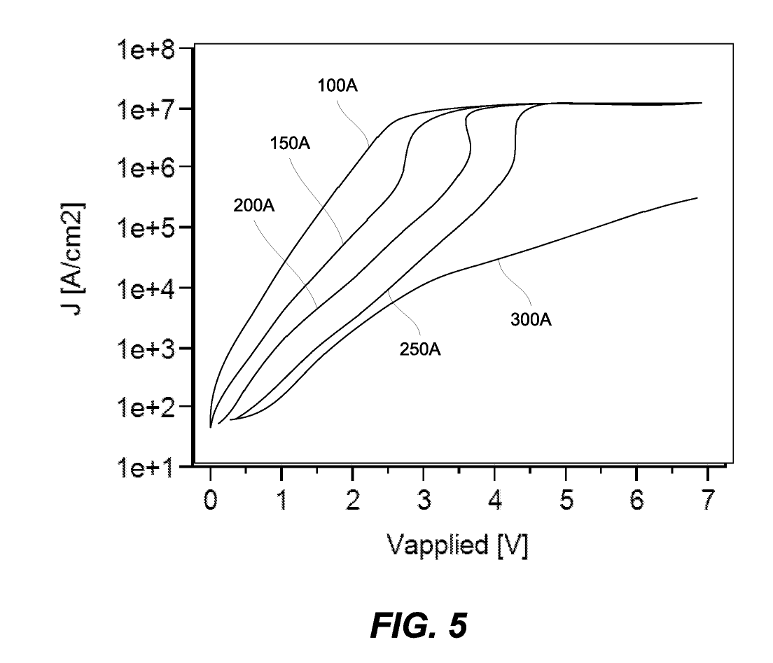

In some embodiments, a dielectric layer may comprise silicon and/or germanium. For example, a selector element may be formed by positioning a silicon layer between two layers of carbon operable as electrodes. FIG. 5 illustrates snapback characteristics of carbon electrode/silicon dielectric/carbon electrode (C/Si/C) stack for different thicknesses of silicon layers. As on can see from this figure, the current shows a rapid increase in range of 3˜5V, in effect, turning from the OFF state to the ON state. Although this C/Si/C stack shows an S-shape non-linear characteristic (snapback), there are a number of issues that may this stack not usable for some application. One issue is associate with a thickness needed for some threshold voltage (Vₜₕ) values. For example, in order for the threshold voltage (Vₜₕ) to be in the range of 3.5˜4.5V (e.g., used for some memory applications), the dielectric layer thickness needs to be at least about 200 Angstroms. This thickness requirement may be unacceptable for some advanced memory applications. For example, many current design limit dielectric thicknesses to less than about 100 Angstroms. Another issue is that the leakage current of this stack (when the selector is in the OFF state) is too high, for example, in micro Ampere range. For advanced memory application, this leakage rate needs to be substantially smaller, such as in nano Ampere range. Finding a selector stack which meets the threshold voltage (Vₜₕ), thickness, and leakage current specifications is a major challenge. This challenge is addressed by doping carbon electrodes.

Specifically, it has been found that the snapback characteristic of C/Si/C selector stack can be significantly improved if one or both carbon layers are doped with silicon, germanium, selenium, or other suitable dopants. The concentration of dopants in the carbon layer may be between about 5 atomic % and 50 atomic % or, more specifically, between 10 atomic % or 30 atomic %. In some embodiments, the dopant is silicon. Alternatively, the dopant may be a gaseous dopant, such as oxygen or nitrogen.

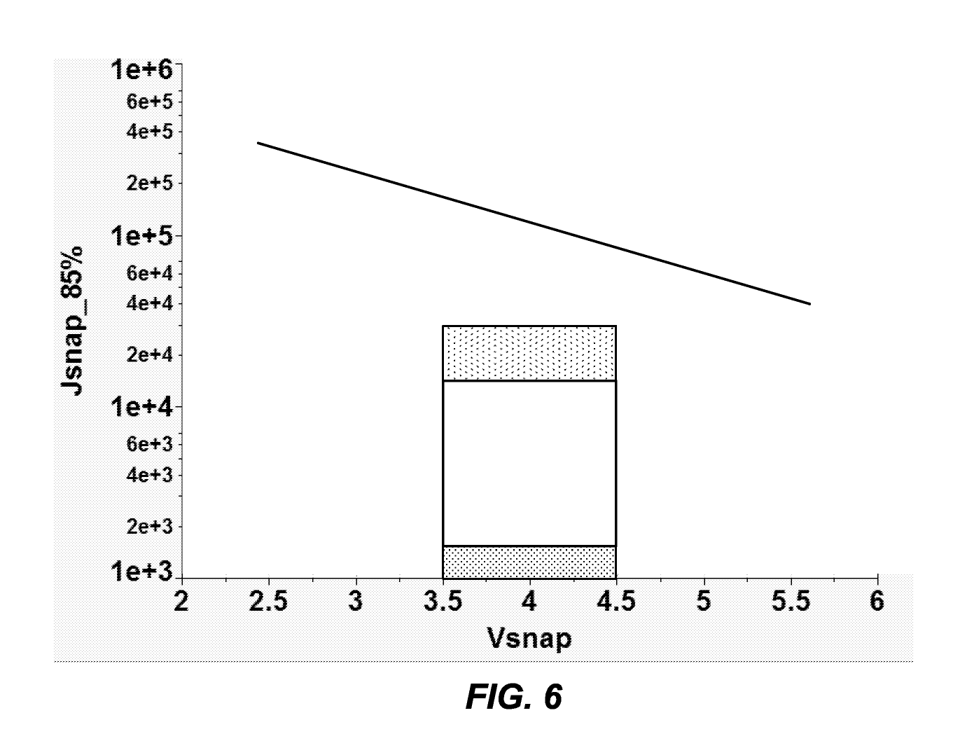

Addition of dopant changes the Si/C interface and results in more stable leakage characteristics as shown in FIG. 6. Specifically, doping the carbon layers reduces the leakage, which normally increases from the first fire to the tenth triggering cycle during selector operation. Furthermore, stacks with doped carbon layer also maintain the leakage level as the current density compliance is increased from 5×10⁶ A/cm² to 1×10⁷ A/cm². At Jmax=1×10⁷ A/cm², several devices configurations are possible.

It should be noted that the electrode doping approach may be used with a dielectric layer formed from silicon or form an alloy of the two or more materials described above.

In some embodiments, current selectors, and methods to fabricate such selectors, for resistive-switching memory elements and cross point memory array are provided. The selector can be fabricated in accordance with configurations described above. The fabrication process of the selector may utilize low thermal budget, suitable for back end or 3D memory applications.

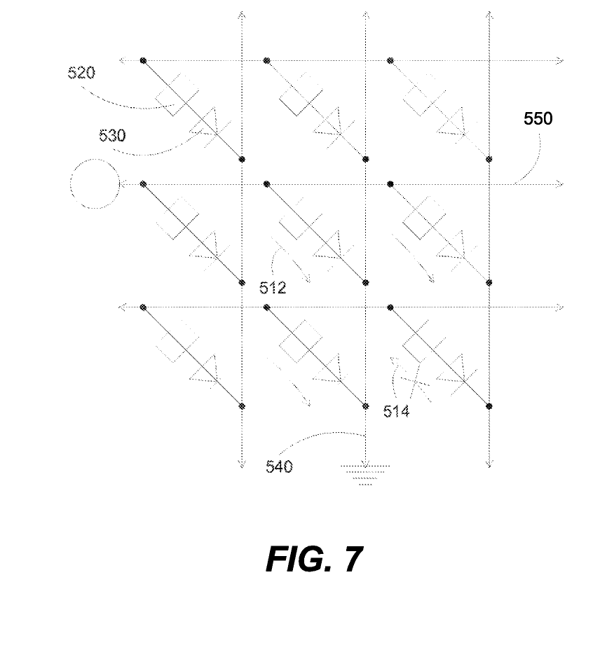

To reduce or eliminate the sneak path occurrence a selector can be used in the cross point memory array. The selector can isolate the selected memory cell from unselected memory cells by breaking parallel connections of the memory cells. FIG. 7 illustrates a cross point memory array according to some embodiments. A memory device can include memory element 520 and selector 530, which are both disposed between electrodes 540 and 550. Selector 530 can be an intervening electrical component, disposed between electrode 530 and memory element 520, or between the electrode 540 and memory element 520. In some embodiments, selector 530 may include two or more layers of materials that are configured to allow or inhibit the current flow in different directions through memory element 520 when that memory element is not selected to read. In some embodiments, selector 530 can prevent a sneak path current when, for example, a sense current is generated.

### Conclusion

Although the foregoing concepts have been described in some detail for purposes of clarity of understanding, it will be apparent that certain changes and modifications may be practiced within the scope of the appended claims. It should be noted that there are many alternative ways of implementing the processes, systems, and apparatuses. Accordingly, the present embodiments are to be considered as illustrative and not restrictive.

What is claimed is:

1. A selector element having a snapback characteristic, the selector element comprising:
a first electrode;
a dielectric layer; and
a second electrode,
wherein the dielectric layer is disposed between the first electrode and the second electrode,
wherein the dielectric layer is characterized by a thickness extending in a direction between the first electrode and the second electrode,
wherein the dielectric layer comprises an alloy of a first material and a second material, and
wherein a concentration of the first material and a concentration of the second material in the alloy vary throughout the thickness of the dielectric layer.

2. The selector element of claim 1, wherein the first material is selected from the group consisting of germanium, indium, and aluminum, and wherein the second material is selected from the group consisting of silicon, a combination of gallium and arsenic, and a combination of arsenic and antimony.

3. The selector element of claim 1, wherein the first material is germanium, and wherein the second material is silicon.

4. The selector element of claim 1, wherein the first material is selected from the group consisting of indium and aluminum, and wherein the second material is selected from the group consisting of a combination of gallium and arsenic and a combination of arsenic and antimony.

5. The selector element of claim 1, wherein the first material is indium, and wherein the second material is selected from the group consisting of a combination of gallium and arsenic and a combination of arsenic and antimony.

6. The selector element of claim 1, wherein the first material is indium, and wherein the second material is a combination of gallium and arsenic.

7. The selector element of claim 1, wherein the first material is indium, and wherein the second material is a combination of arsenic and antimony.

8. The selector element of claim 1, wherein the first material is aluminum, and wherein the second material is a combination of gallium and arsenic.

9. The selector element of claim 1, wherein the concentration of the first material and the concentration of the second material in the alloy vary gradually throughout the thickness of the dielectric layer.

10. The selector element of claim 1, wherein the concentration of the first material and the concentration of the second material in the alloy vary linearly throughout the thickness of the dielectric layer.

11. The selector element of claim 1, wherein the concentration of the first material increases from a side of the dielectric layer facing the first electrode to a center of the dielectric layer.

12. The selector element of claim 1, wherein the first electrode comprises carbon and a dopant.

13. The selector element of claim 12, wherein the dopant of the first electrode is one of silicon, germanium, or selenium.

14. The selector element of claim 12, wherein the dopant of the first electrode is one of nitrogen or oxygen.

15. The selector element of claim 12 wherein the dopant has a concentration on the first electrode of between about 5 atomic % and 50 atomic %.

16. The selector element of claim 12, wherein the dopant has a concentration on the first electrode of between about 10 atomic % and 30 atomic %.

17. A non-volatile memory cell comprising:
a non-volatile memory element;
a selector element connected in series with the non-volatile memory element, wherein the selector element comprises:
a first electrode;
a dielectric layer; and
a second electrode,
wherein the dielectric layer is disposed between the first electrode and the second electrode,
wherein the dielectric layer is characterized by a thickness extending in a direction between the first electrode and the second electrode,
wherein the dielectric layer comprises an alloy of a first material and a second material, and
wherein a concentration of the first material and a concentration of the second material in the alloy vary throughout the thickness of the dielectric layer.

18. The non-volatile memory cell of claim 17, wherein the non-volatile memory element is a resistive switching memory element.

19. The non-volatile memory cell of claim 17, wherein the first material is selected from the group consisting of germanium, indium, and aluminum, and wherein the second material is selected from the group consisting of silicon, a combination of gallium and arsenic, and a combination of arsenic and antimony.

20. The non-volatile memory cell of claim 17, wherein the first material is germanium, and wherein the second material is silicon.
